(19) United States
(12) Patent Application Publication
(10) Pub. No.: US 2006/0001496 A1
(43) Pub. Date: Jan. 5, 2006

(54) Array oscillator and polyphase clock generator

(76) Inventors: Igor Anatolievich Abrosimov, St. Petersburg (RU); Alexander Roger Deas, Edinburgh (GB)

Correspondence Address: Maria Nilova, 58, Moika Embankment, Saint-Petersburg, 190000, RU

(21) Appl. No.: 10/882,236

(22) Filed: Jul. 2, 2004

(51) Int. Cl. H03K 3/03

(52) U.S. Cl. 331/57

(57) ABSTRACT

The present invention relates generally to array oscillator circuits for use as phase delay generators. More particularly, the present invention relates to a novel array oscillator for providing a plurality of phases which have stable phase relationships. The present invention is particularly applicable to the generation of poly-phase clocks for receivers of very high speed interfaces which employ an over-sampling technique, or multiplexing, and for high speed logic. The array oscillator according to the invention comprises at least one ring oscillator having a plurality of at least two interconnected buffer stages including at least one, or any integer odd number of inverting stages and a series of non-inverting stages, wherein the buffer stages are formed of N-type MOSFET transistors.

### BACKGROUND OF THE INVENTION

1. Technical Field

The present invention relates generally to array oscillator circuits for providing a plurality of phases which have stable phase relationships.

The present invention is particularly applicable to the generation of poly-phase clocks for receivers of very high speed interfaces which employ an over-sampling technique, or multiplexing, and for high speed logic.

2. Background of the Invention

Ring oscillators are very well known and have been used for many decades to generate a clock signal. The simplest such oscillator is an inverter with the output fed back to the input. To ensure the oscillation covers sufficient voltage or current swing to represent a logical 0 and 1, a Schmitt oscillator is often used. Thirty years ago, this was often a 7414 TTL device. The oscillation frequency was often set using a low pass RC circuit (series R from 7414 output to input, and capacitor from input to ground). These oscillators were probably the most widely used oscillators in any digital system.

In high speed circuits the single inverter is replaced by a series of inverters, such that there is sufficient delay through the inverters to allow time for the output to slew from a logical low to a logical high, and high to low, depending on the state of the oscillation.

In general, the ring oscillator comprises an inverter with feedback from the last stage to the first. The inverter may be formed by one stage, or an odd number of inverting stages with any number of non-inverting stages, such that there is sufficient delay through the series inverters for the signal to swing from 0 to 1. The inverter may be an inverting amplifier, NOR gate, or anything else that gives a 180 degrees phase shift with gain. Different gates or circuits can be used in the chain. The key point is that there is a 180 degrees phase shift from the input to the output of the chain. The period of the oscillation is twice the delay through the chain and any filter components in the chain.

For example, if one inverter has a 150 ps delay time and has a 100 ps rise time and 100 ps fall time, then simply coupling the output to the input of the inverter will produce a digital ring oscillator. The speed of the oscillation can be varied by adding delay to the feedback or slowing down the inverter further. As another example, if an inverter has a 50 ps delay and a 100 ps rise and fall time, then if the output of this inverter is connected to the input, the peak to peak swing would not be a full logic 1 or 0. In this case, at least 3 identical inverters would have to be used, or one inverter and two non-inverting buffers.

A ring oscillator built out of a large number of inverting stages will have more than one mode. In practice, jitter eventually causes clocks to coincide, such that the only long term stable state is a 180 degrees phase shift through the chain, and this is known as the fundamental mode.

It is not normally required to reset ring oscillators to the fundamental mode, but this can be done by breaking the chain by turning off one inverter, such as by using a NOR gate for the inverter. Use of Exor gates to turn off a stage may found occasionally in ring oscillators where a higher mode of oscillation than the fundamental is desired. The difficulty in maintaining these higher modes is such that for the purposes of describing the present invention, only the fundamental mode will be considered and all oscillators described herein work in that fundamental mode.

High speed digital systems commonly use clocks derived from a Voltage Controlled Oscillator (VCO), which is often a ring oscillator locked using a Phase Locked Loop (PLL) to a reference clock such as from a crystal oscillator. The frequency of the VCO is a function of the divide chain in the PLL and the crystal reference frequency. The k of the PLL, that is the ratio of the feedback to the ring oscillator frequency, depends on how the ring oscillator is controlled. Common schemes involve adding a varicap diode (a reverse biased diode in series with a capacitor, such that the bias on the diode determines its capacitance), or controlling the bias in the inverter or buffer stages such as is described in WO 03/100973 by the inventors of the present invention.

Single ended logic can be used for low speed ring oscillators, but at very high speeds, differential current mode logic becomes necessary. Differential buffers and gates have been known for many decades. The earliest integrated circuits used differential logic, such as in many ECL devices. There has been widespread use of differential current mode logic in CMOS technologies to implement high speed gates. A useful characteristic of differential stages is that whether they invert or simply buffer the signal is determined by the connections into the stage: simply swapping the two input pins on a differential inverter turns it into a differential buffer, which is the same in all other aspects to the inverter. Where the VCO control is via the bias of the differential stage, this commonality in circuitry can be useful.

Generation of two non-overlapping phases can be accomplished very easily, using just three gates driven from a VCO. Generation of more than just two phases will use typically a poly-phase clock generated with a ring oscillator type VCO, as shown in FIG. 2. The drawback of this approach is that the phase resolution is limited to the delay through a single stage. Many applications require a better phase resolution than this.

Improved phase resolution can be achieved using a ring oscillator and any multi-tap delay element. However the distribution of the phases tends to be uneven because the delay through the gain stage or inverting stage is usually much larger than the spacing between the taps on the delay chain.

A further factor in the design of poly-phase clocks is the need for low jitter. For example, some standards, such as the 10.3 Gbps XFI bus from the XFP consortium, or SONET OC192, specify very low levels of jitter. This requires attention to minimise noise from any poly-phase clock.

One method of reducing the phase noise further is to globally lock the oscillator. In the most general sense, this is described in the paper “Phase Noise in Externally Injection-Locked Oscillator Arrays” by H-C Chang, X Cao, M. Vaughan, U. Mishra and R. York, in IEEE Transactions on Microwave Theory and Techniques, Vol. 45, No. 11, November 1997.

Multiple ring oscillators or registers can be used to generate a poly-phase clock, such as in U.S. Pat. No. 5,268,656, and U.S. Pat. No. 5,347,234, but these designs are limited to lower frequencies than are considered here and the phase relationship tends to be unstable.

Obviously, any type of inverting buffer can be used in a ring oscillator. Differential buffers are well known, and these are used in U.S. Pat. No. 5,426,398. It is noted that the buffers in the implementation described in U.S. Pat. No. 5,426,398 suffer from speed limits due to the use of P-type pull up transistors and common biasing.

The phrase “array oscillator” is used in U.S. Pat. No. 5,717,362 and its continuation U.S. Pat. No. 5,475,344 by Maneatis and Horowitz after first use in 1993 ISSCC paper describing a similar circuit. Both these patents contain discrepancies between text and figures, which makes it very hard to understand what is being described, and none of the circuits described in the patent were found by the inventors to work when simulated with SPICE. However, the fact that the inventions described in these patents are aimed at achieving the same technical effect as the present invention, makes these two patents worthy of detailed analysis.

Both U.S. Pat. No. 5,717,362 and its continuation as U.S. Pat. No. 5,475,344 refer to an array of differential or single ended inverting buffers with “substantially identical electrical characteristics”. That is every stage has a 180 degrees phase shift at DC if the inputs to the stage are the same. Each inverter stage comprises two inverters that are effectively connected in parallel, one being marked as a C (coupling) input and the other an S (series) input. The output is the mean of the two inputs, and this has the effect that the output is half way in phase between the phase of the two inputs during dynamic operation of the oscillator. The array is built from rows of these inverters “coupled together in a particular manner”. The patents state these stages are all identical to one another “with adjacent rings offset in phase by a fixed delay” and that “within the array an equivalent signal delay must exist through all array interconnections”. The patent states all these arrays operate in their fundamental mode, that is the period of the oscillation is twice the delay through any one of the rings.

There are three problems with these two patents which must be considered before their utility can be understood.
1. The text and Figures in these two patents contradict each other many times, giving rise to multiple possible interpretations of what is described. These must be overcome by exhaustive searching for all possible variants of interconnect and simulating each of these.
2. None of the three actual “manners” of coupling the arrays that are given as examples in the patent were found to work when an engineer simulated these in SPICE using CMOS inverters as described in the patent.
3. There appears to be no way of connecting an array of identical stages such that they operate in fundamental mode. This means the performance of any array oscillator of the form described in U.S. Pat. No. 5,717,362 and U.S. Pat. No. 5,475,344, is unpredictable, both in the frequency at which it operates and the phases it generates.

Each of these problems will be considered in turn.

The first issue is to sort out what the patent is actually describing, and foremost in this is determining in what mode the rings operate. Fundamental mode operation is very highly desirable for any ring oscillator. The reason fundamental mode is strongly preferred is that any other mode tends to be unstable and to die out eventually due to noise. Unfortunately, as the inventors of U.S. Pat. No. 5,717,362 and U.S. Pat. No. 5,475,344 correctly state, “when the array is again closed, the array will begin to oscillate at the mode closest to the fundamental mode, i.e., the mode producing the highest oscillation frequency”. This means that unless the array operates properly as a series of fundamental mode rings, it is very difficult to predict what the output frequency will be at any moment in time.

FIG. 4 of U.S. Pat. No. 5,717,362, and the Figure on the front page and FIG. 4 of U.S. Pat. No. 5,475,344 are the same. This figure is absolutely key to these two patents, as no-where else is there drawn any of the coupling feedback that is crucial to the operation of the array oscillator. The patent states that all the other diagrams use the same feedback scheme as illustrated in FIG. 4. For stable operation, it must be possible to label each stage with a phase shift, such that each stage has the same phase shift, and for fundamental mode operation, the maximum shift from any point to any point in the array is 180 degrees. It appears that it is not possible to achieve this for any array described in these two patents. This means that if the arrays work, they must work at a higher mode than the fundamental. This is in contradiction to the text of the patent.

Description of FIGS. 3A and 3B refer to a fundamental mode, where there is a 180 degrees phase shift through each ring, but FIG. 3 clearly shows the second mode (2× the fundamental, with an entire period existing within each ring). The text relating to FIG. 2 also describes fundamental mode operation when it states “The delay through each buffer inverter is equivalent to the period of the reference signal divided by 2N”. In fact, second mode operation is divided by N. On column 7 the inventors describe FIG. 8 and again state it is operating in fundamental mode: “The oscillation period for each ring R is equivalent to a buffer delay scaled by twice the number of bugger stages included therein”. In describing FIG. 7 in column 8, the inventors state “and if it is assumed the array is phase locked to a reference clock signal of period T, then the delay D of each buffer stage may be expressed as T/2N”. The inventors then give various equations, all describing fundamental mode. The inventors then state “The period of oscillation T(C) of each ring R within the array oscillator, as a function of coupling factor C, is equivalent to 2ND(C).” The coupling factor is 1, therefore this is a fundamental mode oscillation.

There are five stages in FIG. 4, so in fundamental mode each stage has a 36 degree phase shift (180 degrees divided by 5 is 36). With a 36 degrees phase shift per stage, the coupling (c) inputs to each of the inverter stages do not have any stable phase relationship to the (s) inputs with the feedback shown in FIG. 4: for example, the feedback is not a constant S−18 degrees as one would expect, nor is it S+18 degrees, nor S+36 degrees or S−36 degrees, nor S−72 degrees or S+72 degrees. This means the array does not work in fundamental mode as purported. Nor do any of the other array configurations described in either of these patents.

Scrutiny of the text reveals that a different feedback configuration to the Figures is described on page 5 of U.S. Pat. No. 5,717,362: that is the text contradicts the diagram for this key FIG. 4 (the only one showing the feedback). The feedback configuration described in the text is “array outputs P9, P10, P6 and P7 being coupled to C2, C3, C4 and C5”. Later on the same page is the sentence “the constituent ring oscillators are connected such that transitions in the signals applied to the coupling (C) and Signal (S) ports will be at least partially overlap (sic) in time”. Unfortunately, none of C2, C3, C4 or C5 are marked on any drawing, but it is logical to assume that C2 is the C input of P2. The reader must choose between the Fig. or the text, because if P9 output was connected to C2 (being P2 C input), then it would short out the P8 output coupled to the same C2 input. Discrepancies and missing labels such as this on this key Fig. do not aid the understanding of these two patents.

It is not possible to arrange the feedback in any of the array oscillators drawn in these two patents, U.S. Pat. No. 5,717,362 and U.S. Pat. No. 5,475,344, to create a constant phase relationship between the S and C inputs of each stage with the oscillators operating in their fundamental mode. Without such a constant phase relationship, these earlier inventions simply fail to work as described.

All array configurations in these earlier patents show identical stages. For example, as in FIG. 7 from U.S. Pat. No. 5,717,362 and U.S. Pat. No. 5,475,344, which is reproduced as FIG. 6 herein. There is no way to connect the feedback within an array of identical stages such that each stage has the same relative phase shift on its inputs, if the maximum phase shift within the array is 180 degrees. With an uneven phase relationships on the C and S inputs of the stages, the array oscillator either fails to work at all or its fundamental mode operate with large amounts of phase noise or jitter, depending on the exact feedback used.

In an attempt to make the array oscillators of U.S. Pat. No. 5,717,362 and U.S. Pat. No. 5,475,344 operate at all, the consideration will now be expanded to include rings which operate at a higher mode than the fundamental. This is contrary to the text of these two patents but it is in accord with the Figures which refer to ring oscillators where a whole period is represented in each ring, that is 360 degrees and not 180. Under these circumstances, then it is possible to connect the feedback such that each stage has the same relative phase relationship. This is not the fundamental mode, and there is the risk this mode will die out sooner or later due to noise, and there is a difficulty in predicting the frequency at which the oscillators operate.

There are three oscillators described in these two patents: a 2 row 5 stage array (FIG. 4 in each patent), a 5×5 array mentioned in the text and a 7×5 array also mentioned in the text. Detailed SPICE simulation shows that none of these work as an array oscillator.

In FIG. 7, SPICE simulation of the array in FIG. 4 of U.S. Pat. No. 5,475,344 (FIG. 3 herein), using library inverters (TSMC 0.18 um CMOS 6 Layer Metal Process, CLKINVX8 inverters), is shown. As follows from FIG. 7, the array in FIG. 4 operates as a single ring oscillator with a period of 20 inverter delay. That is, it does not have any benefit at all over a single ring oscillator and operates in the same manner as the prior art but more slowly. In FIG. 10 herein, which is an interpretation of the array oscillator of FIG. 7 from U.S. Pat. No. 5,475,344, the phase shift of every wire is marked on the drawing, as are all the feedback paths. The simulation results are shown in FIG. 11. The frequency of oscillation is around 2.3 GHz (a period of 0.44 ns). The delay for a CLKINVX8 inverter is around 120 ps in a ring oscillator with loads the same as FIG. 4.

Even a theoretical consideration of FIG. 7 of U.S. Pat. No. 5,475,344 (FIG. 6 herein) highlights problems. Labelling every stage with the phase shift on its output to achieve a 180 degree shift for each ring, such that the phase shift through each stage is identical shows that each inverter must each have a 216 degrees phase shift instead of 180 degrees. For example, consider the first inverter pair, generating the 36 degrees phase signal. The inputs to the pair are 180 degrees and 198 degrees. The mean input signal is therefore 189 degrees. The inversion creates 9 degrees, plus there must be a further 26 degrees due to other phase shift in the inverter due to layout parasitics.

The two other arrays mentioned in the text of the patent, a 7 row 5 column with coupling from stage n+2, and the 5×5 array with n−2 coupling were also simulated. The simulation results are in FIGS. 8 and 9, showing that neither of these work either.

Unfortunately, without any of the Figures in these two patents showing the full feedback scheme, and the inconsistency between text and Figures, much interpretation is needed. It is possible to implement every variant of feedback scheme within every array combination up to 5×5. After performing such an exhaustive set of implementations, it transpires that very few feedback schemes work in any mode. Searching all possible coupling schemes between rows of identical stages in all array combinations up to 5×5 revealed that the most effective scheme of connecting identical stages is as shown in FIG. 10 herein, with SPICE simulation results shown in FIG. 11. In this diagram, all the feedback paths are shown, and they are labeled with the phase delay so it can be understood easily.

In FIG. 10 the S and C inputs are expanded: the dual input inverters are shown in these earlier patents to be simply two inverters in parallel. This Figure and the simulation result are intended purely as an aid to the reader in understanding how these two earlier patents could possibly be made to work and how they relate to the present invention.

The scheme in FIG. 10 uses feedback of N+1. N−1 is also useful. For even these improved schemes, the results are unpredictable. For these small arrays, there are two possible lengths of each ring in this range: 3 stages and 5 stages. Arrays with 2, 3, 4 and 5 rows were simulated.

| | | | |
|---|---|---|---|
| Rows | Period of osc | Phase delay per stage | Phase resolution |

3 Gates per ring

| | | | |
|---|---|---|---|
| 2 | 672 | 112 | 1 |
| 3 | 440 | 49 | 0.33 |
| 4 | 374 | 31 | 0.25 |
| 5 | 1820 | 121 | 1 |

5 Gates per ring

| | | | |
|---|---|---|---|
| 2 | 1120 | 112 | 1 |
| 3 | 736 | 49 | 0.33 |
| 4 | 629 | 31 | 0.25 |
| 5 | 582 | 23 | 0.2 |

The phase resolution tabulated is normalised to one inverter delay.

All of these circuits operate in higher modes than the fundamental.

With three stages per ring, the 2×3 array oscillates simply at the highest mode, namely the same as a ring oscillator of 6 stages, but the 3×3 and 4×3 arrays worked as an array oscillator. The 5×3 array failed to operate correctly, and reverted to the same mode as the 2×3 array.

With five stages per ring, the 2×5 array had the same problem as the 2×3 array, but the 3×5, 4×5 and 5×5 arrays worked, albeit in modes other than the fundamental.

The large phase offset between the two inputs to the inverter pair comprising each stage meant that the exact frequency varied over a wide range: from 1.36 GHz to 1.72 GHz.

Due to the unstable nature of non-fundamental mode operation, changes to the loading of the stages, such as by the circuits they drives, can change their operating mode, but in no instance has this mode been observed to be the fundamental mode.

The conclusion of an analysis of U.S. Pat. No. 5,717,362 and U.S. Pat. No. 5,475,344 is that the oscillators do not operate as described, none of the example embodiments operate correctly, and oscillators of the general type described by these patents are both slow and unpredictable. The mode in which these oscillators operate, may cause them to be slow to start up. A working example and tabulation of oscillators of the general type described in these two patents has been given for the first time herein.

The problems with the array oscillators in the 1993 ISSCC paper, U.S. Pat. No. 5,717,362 and U.S. Pat. No. 5,475,344 are addressed partially in U.S. Pat. No. 6,222,406 and U.S. Pat. No. 6,414,530, both by Noda et. al. The oscillator in FIG. 21 of U.S. Pat. No. 6,222,406 is one of the variants we have interpreted from U.S. Pat. No. 5,475,344, with the phase diagram corrected. Various examples of stages are given in FIG. 4 of that patent. However, the resulting phase diagram is not equi-spaced. The inventors in paragraph [007] recognise the problems of long start up times in the earlier work. The main way they try to overcome this is by splitting the array such that it acts as a delay generator, and drive the array from an external oscillator. In attempting to make the array oscillate on its own, as in their FIG. 21, the same problems of multi-modal operation are encountered. There is no set of phases for the array oscillators shown in that patent that can achieve a fundamental mode oscillation: that is where each stage has the same phase relationship on its inputs and the maximum phase in the array is 180 degrees. This is one factor which gives rise to unequal phase distribution, as can be seen in FIG. 6 of that patent. In that FIG. 6, the delays vary from 50 ps (stage 3-4) to 1.2 ns (Stage 1). The primary innovation of Nova is to add a coupling capacitor between the two inputs of the array, to assist in creating the phase delays required: as we have already shown, the array oscillators according to the 1993 ISSCC paper, generally require a phase shift per stage of more than 180 degrees.

A limitation with all of the prior art is that they are limited in their speed by the use of single ended inverters, or differential buffer stages based on using a well known buffer circuit, shown in FIG. 10, which reproduces FIG. 16 from U.S. Pat. Nos. 5,475,344 and 5,717,362. Particular reference is made in the patent to having both first and second transistors equally sized and being of P type. The diode connection is also inherent to the invention. The pull-ups using P type transistors, act as resistors with a high capacitance. The use of resistors, such as poly-silicon resistors, is not practical because the parasitic capacitance these carry is even higher than for the P type MOSFETs.

The use of a delay for a ring oscillator such as in U.S. Pat. No. 6,348,839 is similar to U.S. Pat. No. 5,268,656, again using P Type MOSFETs, with the same performance problem.

VCOs with negative feedback to reduce phase noise are known, such as in U.S. Pat. No. 6,353,368. All VCOs use negative feedback, but in this case the biasing is arranged so as to have particular advantage with respect to phase noise.

Poly-phase clock VCOs are known, where phases are selected by a phase selector, such as in U.S. Pat. No. 6,621,313, but again the maximum frequency is limited. A similar restriction applies to interlinked PLLs such as in U.S. Pat. No. 6,657,466.

### BRIEF SUMMARY OF THE INVENTION

Object of the Present Invention

It is therefore a primary object of the present invention to provide a polyphase clock generator which can operate at very high speed.

It is another primary object of the present invention to reduce the jitter in the poly phase clock over the prior art.

It is another primary object of the present invention to improve the timing accuracy of the clock.

A particular form of the invention is suitable for use in the receivers of communication systems in Rapid IO®, PCI Express, Infiniband®, 10GbE, 10GFC, OC192, OC768 and other high speed communications standards.

Summary of the Invention

The present invention in its most general form can be defined as a ring oscillator built up of a plurality of at least two interconnected buffer stages including at least one, or any integer odd number of differential inverting stages and a series of non-inverting stages such that there is a 180 degrees phase shift or odd multiple thereof through the ring oscillator.

Preferably, each buffer stage comprises a set of load elements wherein at least one load element is formed of N-type MOSFET transistors; the load elements being connected to control voltages for controlling the amplitude of output signals, and connected through switch transistors to current source transistors controlled by current source biases for controlling the frequency of output signals.

According to another example implementation of the invention, an array oscillator is provided which generates up to m*n phases from m interconnected ring oscillators of n stages each, the array oscillator comprising a plurality of ring oscillators, wherein each ring oscillator is as described above.

For the above array oscillator, two sets of voltages, including load control voltages and bias control voltages, are generated by the use of replica bias circuitry so that the load control voltages depend on bias voltages and are derived from these voltages. Each set of voltages includes a static and dynamic voltages.

Preferably, the array oscillator according to the invention comprises at least two, or any even number of ring oscillators, each ring oscillator having at least 2 stages, including one inverting and one non-inverting stage.

Another preferable example implementation of the array oscillator comprises 4 ring oscillators, each having one inverting stage and three non-inverting stages.

Still one more example implementation of the array oscillator further comprises a supplemental circuit built of isolation buffers, for providing additional technical effect consisting in that the circuit prevents from affecting the array oscillator by a noise generated by external load devices connected to the array oscillator.

Preferably, all stages of the array oscillator are formed from identical differential inverters. Preferably, non-inverting stage are formed by swapping two inverting inputs to the stage.

Preferably, the stages are coupled to other ring oscillators in the array such that the phase shift through each stage is the same throughout the array, with all the feedback paths being of the same type except for one path which shall be of the opposite polarity to the others.

Preferably, each stage is a buffer, inverter or gate, arranged in series such that each row has a phase shift which is 180 degrees or a multiple thereof from the longest feedback path within the row, normally the input to the row to the output of the row, and the gain from that input to output is more than 1.

Preferably, the number of ring oscillators (n) is at least 2, and each ring oscillator has at least 2 stages.

It shall be further appreciated that the inventive concept of the present invention is based on a combination of some basic features which can be varied to a certain extent to obtain various modifications of the invention within the scope of the appended claims.

This combination of features according to the present invention, which provides the technical effect, i.e. results in achievement of a high speed array oscillator for use in communication systems, can be formulated as follows.

First of all, according to the invention, it is essential that N-type MOSFET transistors are used as load elements for buffer stages. The structure of these load elements, the number of transistors, their interconnection can be varied to result in many modifications and alterations of this feature as described in detail with reference to the following specification accompanied with figures. In brief, the load elements can be as described in US application “Pull up for high speed structures” filed 26 May 2004, or as described further with reference to FIGS. 12, 13, 14, 15, as well as various modifications thereof as defined by the appended claims.

Second, the use of N-type MOSFET's requires generating a pair of control voltages, one for controlling the amplitude of output signals and another for controlling the frequency of output signals. Again, it is essential that the two voltages are interconnected so that the load voltages depend on bias control voltages and are derived from them. This feature is interconnected with the choice of the load elements, say, to control a load element formed of one N-type MOSFET transistor, a pair of control voltages as described above is sufficient; while, to control a load element formed of two transistors each, two pair of control voltages, including load static voltage VT, load dynamic voltage VT1 and bias static voltage VJ, bias dynamic voltage VJ1, are required.

Third, a current source shall be provided to enable the operation of the buffer stage. Again, one current source is sufficient for the operation of a buffer stage having load elements each formed of a single transistor, while two current sources are required for more complex loads elements having two transistors, and many variations of those.

Furthermore, different modifications are possible for circuits, typically, replica bias circuits, providing the above control voltages. For this purpose, a prior art replica bias circuit can be used, though a modifications of replica bias circuits as described in the present invention are preferable. Again, these modifications would vary depending on the choice and structure of load elements, as will be described in detail below.

Still another essential feature of the invention is a pair of switch transistors. While one pair of switch transistors is enough to enable the operation of a buffer stage functioning in a ring oscillator, to built up an array oscillator, the buffer stage is needed which has two pairs of switch transistors.

In connection with the above, according to another aspect of the invention, a differential buffer stage (see FIG. 15) is configured, which can be used to built up a ring oscillator according to the invention, as stated above. The differential buffer stage for receiving differential signals at input signal ports (IN_P, IN_N) and providing complementary buffer stage outputs at output ports (O_P, O_N), comprises:
first (51) and second (52) load elements, connected to a load voltage(VT), for controlling the amplitude of output signals (O_P, O_N), each load element including at least one N-type MOSFET transistor (51, 52) for converting current into voltage;
a static current source (50) to which is applied a static current source bias (VJ),
a pair of switch transistors (53, 54);
wherein the buffer stage is controlled by two voltages, including load control voltage VT and bias control voltages VJ, where VT depends on VJ and is derived from this voltage by the use of a replica bias circuitry.
   A replica bias circuitry for providing control voltages for the above buffer stage comprises (see FIG. 18):
a cascade of at least one load transistor (102) and at least one transistor (104) acting as a current source,
a source (105) of a reference voltage,
an operational amplifier (106) having one input connected to the reference voltage and another input connected to the source of transistor (102);
a transistor (107), having its gate connected to a supply voltage (VDD) and source connected to the output of the amplifier (106), for preventing overvoltages of the load transistor; and
a resistor (108) connected in series between an input voltage VIN and the gates of the load transistor (102);
wherein
a control voltage (VJ) is supplied to the transistor current source (104) to provide a current flowing in the said cascade of transistors (102, 104),
a load voltage (VT) is supplied to the gates of the said load transistor (102) and is further coupled to resistor 108;
thereby the difference between a voltage drop in the load transistor (102) and the reference voltage is amplified by the operational amplifier (106) to control a load voltage (VT) through a feedback formed of said transistor (107) and resistor 108.

In still another aspect of the invention, a differential buffer stage for the above array oscillator is configured (see FIG. 12) to receive differential signals at input signal ports (IN_P1, IN_N1) and input coupling ports (IN_P0, IN_N0) and to provide complementary buffer stage outputs at output ports (O_P, O_N) comprises:
first (21, 22) and second (26, 27) load elements, connected respectively to first, static, and second, dynamic, load voltages (VT, VT1) for controlling the amplitude of output signals (O_P, O_N), at least one load element including a set of N-type MOSFET transistors (21, 22 and 26, 27), for converting current into voltage;
wherein transistors (26,27) are connected in parallel with the drains of transistors (21,22), for dynamic modulation of the load of the differential stage;
a static current source (20) and a dynamic current source (29) to which are applied, respectively, a static and dynamic current source biases (VJ and VJ1),
two pair of switch transistors (23, 25, 24, 28); the drains of the load transistors (21, 22 and 26, 27) being connected through switch transistors (23, 24, 25, 26) to the current source transistors (20, 29) controlled by current source biases VJ and VJ1;
wherein the buffer stage is controlled by two sets of voltages, including load control voltages VT,VT1 and bias control voltages VJ, VJ1, where VT(VT1) depends on VJ(VJ1) and is derived from these voltages by the use of a replica bias circuitry.

According to an example implementation, the above differential buffer stage further comprises a low pass filter for load control voltages (VT and VT1), wherein the low pass filter can be formed by transistors or resistors.

Preferably, current sources are formed by NMOS transistors. Also, preferably, the transistors connected to the same control voltage are equally sized to yield symmetrical current-voltage characteristics.

Preferably, the replica bias circuitry (see FIG. 19) for providing control voltages to the above buffer stage according to the invention includes two replicas for providing, respectively, amplitude control voltages VT, VT1, for controlling an amplitude of the output signal and frequency control voltages VJ, VJ1, for controlling the frequency of the output signal, each said replica circuit comprising:
a cascade of at least one load transistor (82, 82′) and at least one transistor (84, 84′) acting as a current source,
an operational amplifier (86, 86′) having one input connected to a reference voltage and another input connected to the source of the load transistor (82, 82′);
a first resistor (R2; R3) connected between the output of the amplifier and a load voltage (VT, VT1), for avoiding overvoltages of the said cascade of transistors (82, 84, 82′, 84′),
a second resistor (R0, R1) connected between the supply voltage (VAA) and the gate of the load transistor (82, 82′);
wherein a bias control voltage (VJ, VJ1) is supplied to the transistor current source (84, 84′) to provide a current flowing in the said cascade of transistors (82, 84, or 82′, 84′),
a load voltage (VT, VT1) is coupled to the gates of the said load transistor (82, 82′) and is further coupled to resistors R0, R1;
thereby the difference between a voltage drop in the load transistor (82, 82′) and the reference voltage is amplified by the operational amplifier (86, 86′) to control a load voltage (VT, VT1) through a feedback formed by said cascade of transistors (82,84, 82′,84′) and resistors R2, R3.

Preferably, the replica bias circuitry further comprises a transistor (103) for determining the operation point of the load transistor (102).

According to still another aspect of the invention, a voltage controlled oscillator is provided comprising an array oscillator according to the second aspect of the invention, wherein the array is controlled by the use of a replica bias circuitry where changes in the bias cause changes in the delay through each stage.

According to example embodiment, a ring oscillator VCO generates 4*4 phases from 4 interconnected ring oscillators of 4 stage each, wherein each stage is a differential buffer stage according to the present invention as described with reference to FIGS. 12, 13, 14 and 15.

According to still another aspect of the invention, a phase locked loop is provided with very low phase noise comprising a phase detector, a charge pump, low pass filter, a static and dynamic replica bias circuitries, voltage controlled oscillator (VCO) and frequency divider, wherein the VCO is as provided according the above aspect of the invention.

The advantages of the present invention over the prior art is that it provides a high speed, predictable and stable oscillator with phase resolution of less than one stage delay.

### BRIEF DESCRIPTION OF THE SEVERAL VIEWS OF THE DRAWING

For a better understanding of the present invention and the advantages thereof and to show how the same may be carried into effect, reference will now be made, by way of example, without loss of generality to the accompanying drawings in which:

FIG. 1 shows a ring oscillator with the maximum phase resolution being the delay through one stage, FIG. 2 from U.S. Pat. Nos. 5,475,344 and 5,717,362 (PRIOR ART);

FIG. 2. is a 2×5 array oscillator of FIG. 4 from U.S. Pat. Nos. 5,717,362 and 5,475,344 (PRIOR ART);

FIG. 3: Simulation of 2×5 array from FIG. 2 (FIG. 4 of U.S. Pat. No. 5,475,344);

FIG. 4: shows inverter stage from U.S. Pat. No. 5,475,344 (PRIOR ART);

FIG. 5: shows 4×5 array configuration from FIG. 7 of U.S. Pat. Nos. 5,717,362 and 5,475,344 (PRIOR ART);

FIG. 6: SPICE simulation result of 4×5 array oscillator of FIG. 5 (FIG. 7 of U.S. Pat. No. 5,717,362) with each inverter implemented using TSMC 0.18 um CMOS library devices for 8 loads;

FIG. 7: Simulation of 5×5 array from U.S. Pat. No. 5,475,344;

FIG. 8: Simulation of 5×7 array from U.S. Pat. No. 5,475,344;

FIG. 9: Array configuration interpreted from U.S. Pat. Nos. 5,717,362 and 5,475,344;

FIG. 10 shows a differential buffer stage from FIG. 16 of U.S. Pat. Nos. 5,717,362 and 5,475,344 used in array oscillators in the prior art;

FIG. 11 shows a block diagram of an array oscillator of the present invention;

FIG. 12 is a high speed inverter stage of the present invention in its most general implementation;

FIGS. 13 and 14 shows other example implementations of a differential buffer stage used in array oscillators according to the present invention;

FIG. 15 depicts a schematic representation of a preferred implementation of a differential buffer stage called “isolation buffer”.

FIG. 16 shows a schematic representation of an array oscillator VCO with very low phase noise using differential buffer stages as shown in FIGS. 12, 13 or 14;

FIG. 16a shows a schematic representation of a supplemental circuit built up of buffer stages shown in FIG. 15, for the array oscillator from FIG. 16, which prevents noise from external load;

FIG. 17 shows a PLL with very low phase noise with VCO as shown in FIG. 15 above;

FIG. 18 shows a replica bias circuitry of the present invention with very low phase noise, for providing control voltages for the buffer stage according to FIG. 15;

FIG. 19 shows a replica bias circuitry of the present invention with very low phase noise, for providing control voltages for the buffer stages according to FIGS. 12, 13, or 14;

FIG. 20 shows an example layout of an 4×4 array oscillator from FIG. 11 according to the invention;

FIG. 21 shows simulation results of the array oscillator of FIG. 11 according to the invention.

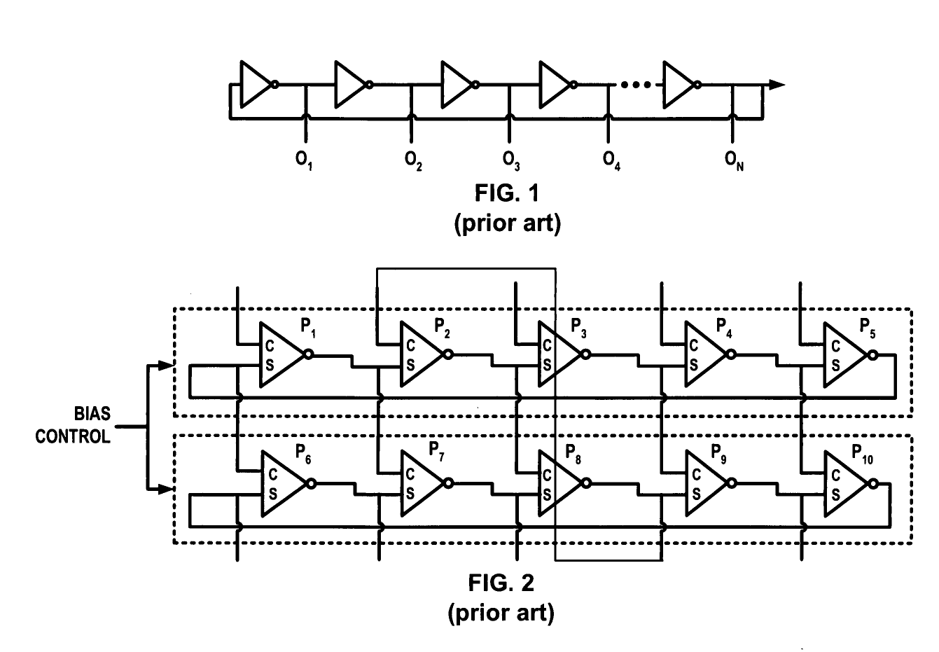

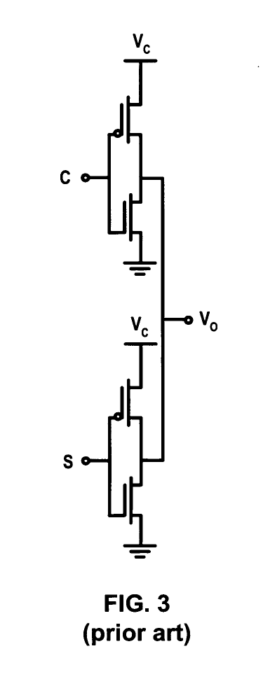

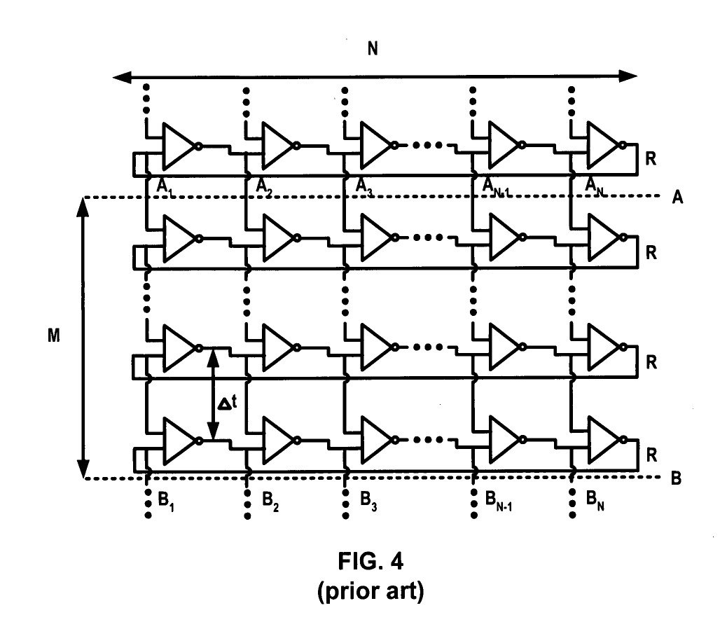

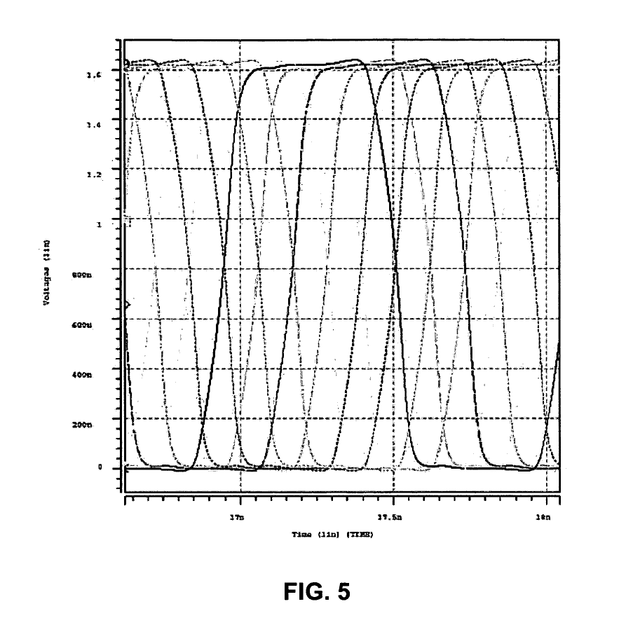

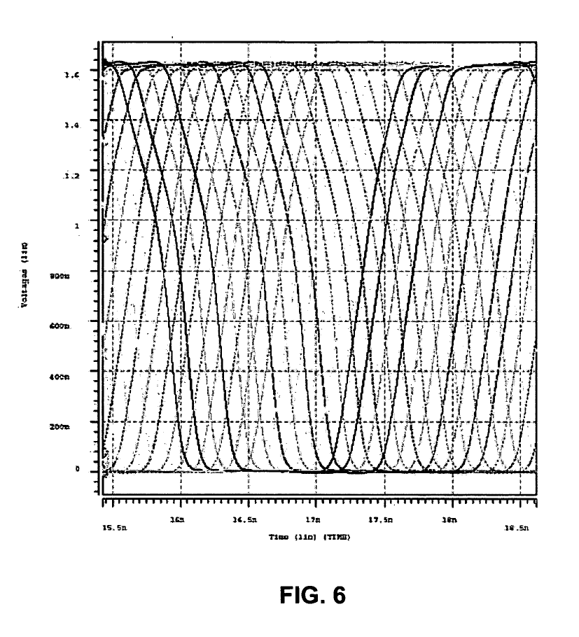

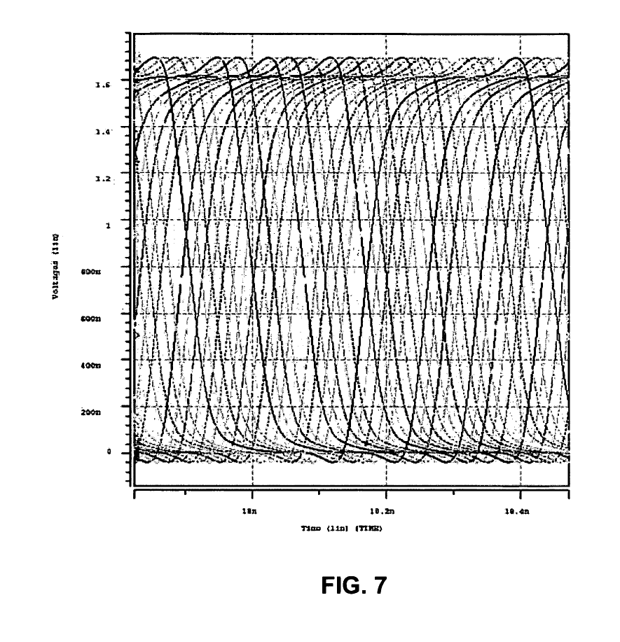

### DETAILED DESCRIPTION OF THE INVENTION

The invention will now be described in detail without limitation to the generality of the present invention with the aid of example embodiments and accompanying drawings.

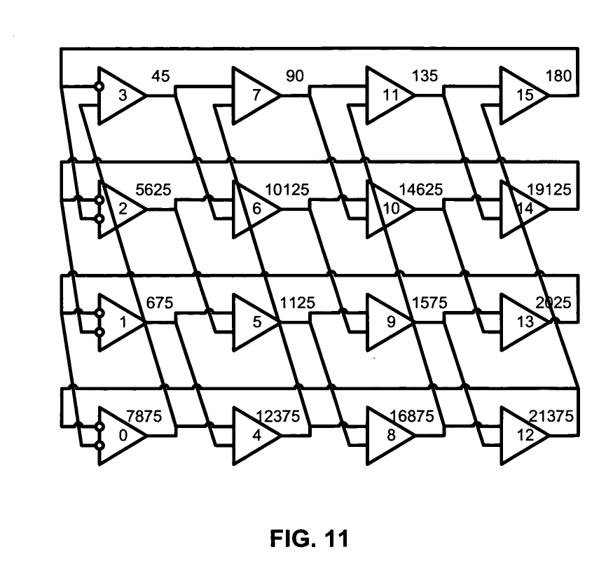

Consider FIG. 11, which is an example of an array of inter-coupled ring oscillators according to the present invention. Each ring oscillator comprises an inverting stage and a series of non-inverting stages. For example, a first ring oscillator comprises inverting stage P0 and a series of non-inverting stages P4, P8, P12 and the second oscillator comprises an inverting stage P1 and non-inverting stages P5, P9, P13). In this embodiment, each stage should be assumed to be the same and formed from a differential inverter. To create the non-inverting stages, the two inverting inputs to the stage are swapped. Each inversion of the signal is represented by a circle with white inside, as is the common practice for engineering drawings.

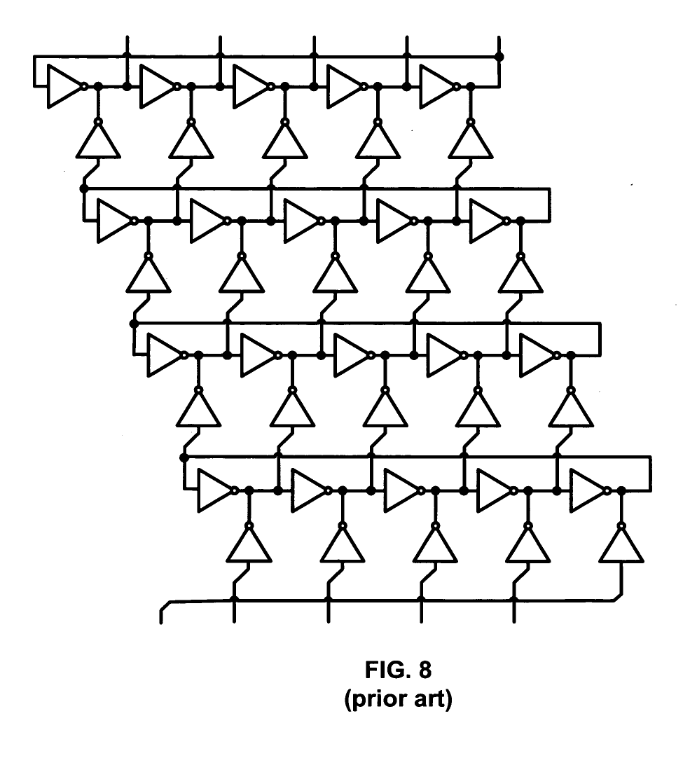

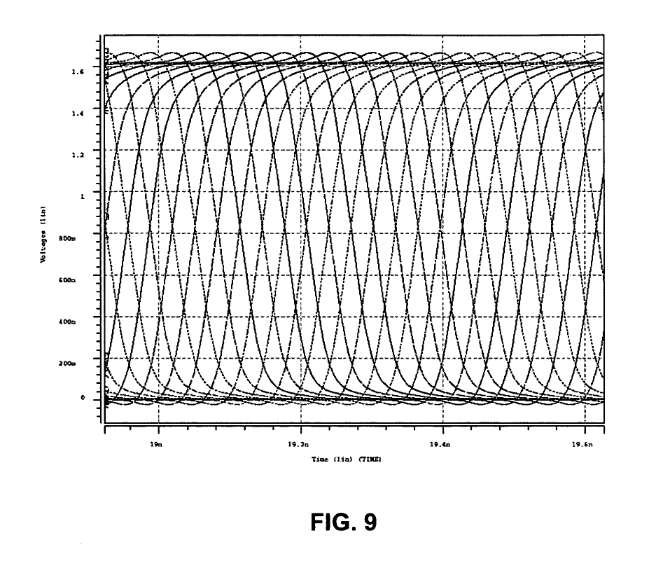

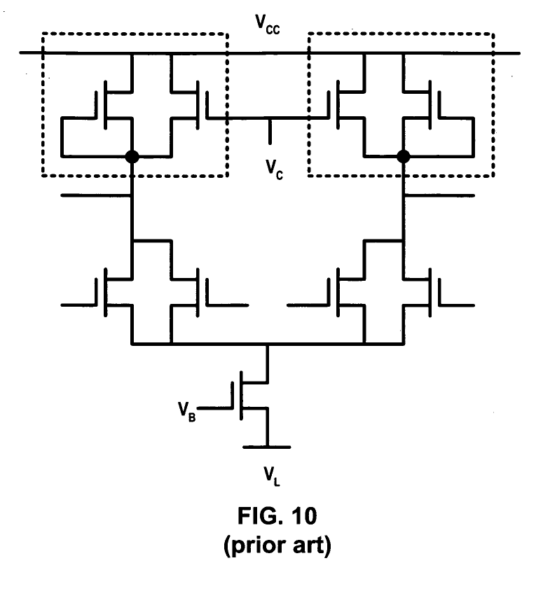

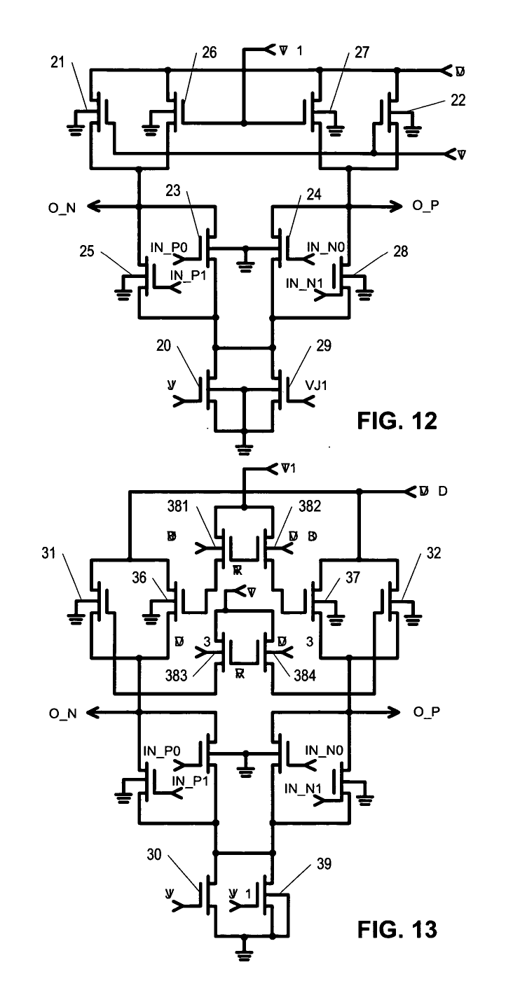

Preferably, the suitable buffer stages are as disclosed by the inventors of the present application in earlier publication WO 03/100974 and its CIP application in US “Pull up for high speed structures”, Ser. No. 10/853,123, filed on 26 May 2004 (with reference to FIGS. 8 and 9 therein), the full specifications of these applications being incorporated herein by reference, or as described further in the present application with reference to FIGS. 12, 13, 14, 15.

In FIG. 12, a differential buffer stage is shown wherein each buffer stage acts as two differential inverters/buffers in parallel.

In more detail, a circuit in FIG. 12 is a differential buffer stage comprising two pair of NMOS transistors 21, 22 and 26, 27 for controlling the amplitude of an output signal, and a pair of transistors 23, 24 which operates as switch. To dynamically modulate the strength of the differential stage during switching, transistors 26, 27 are connected in parallel with drains of transistors 21, 22. Oscillation control voltage VT (static) is applied to transistors 21, 22, while voltage VT1 (dynamic) is applied to transistors 26, 27. The biased NMOS devices 21, 22 and 26, 27 connected to the same control voltage, respectively, are equally sized in pairs, as required by circuitry symmetry, to yield respective symmetrical current-voltage characteristics.

The above circuitry can be used in a voltage generator. Transistors 21, 22 and 26, 27 provides the initial voltage level to start up such a generator. Transistors 23, 24 operate as switches.

The buffer stage further includes two N-transistor current sources 20 (static) and 29 (dynamic) to which are applied current source biases VJ and VJ1, respectively.

A load control voltage VT is supplied to gates of transistors 21, 22, and VT1 is supplied to sources of transistors 21 and 22 via transistors 26, 27.

The buffer stage is controlled by the use of two arrangements (see above VT,VT1,VJ,VJ1). It is configured to receive differential signals at input signal ports (S) IN_P1, IN_N1 and input coupling ports (C) IN_P0, IN_N0 (which can be assumed to be the same as signal ports S) and to provide complementary buffer stage outputs at output ports OUT_P, OUT_N. The operating current and output voltage in the circuit is controlled by load voltage level VT and bias control voltage VJ generated by a replica bias circuitry shown in FIG. 18. This can be used, for example, to control a frequency generator, or the like.

The buffer operates as follows:

The input data is supplied to IN_PO and IN_NO. They are controlled by the voltage levels supplied to VT and VJ, as described above. As a result, a delay and amplitude of the input signal can be regulated by VT and VJ. Respectively, the use of such buffers in voltage controlled oscillators provides varying the frequency of the oscillator by changing voltage.

The advantage of the differential amplifier according to the invention over the prior art is that the strength of the stage during switching can be dynamically modulated by using resistors 26, 27.

Each one of transistors 21, 12 itself has its gate capacitance which, in combination with transistors 26, 27, respectively, forms an equivalent RC network, which gives a delay when this time constant is close to the switching time that changes the current in the stage dynamically. When the voltage on the terminal of the stage goes from a high level to a low level, for a time ts, the strength of the stage is lower because the gate of the transistor is not charged to the final level.

As has already been described above, this results in a faster transition down because the pull down circuitry will see a weaker pull up. When switching is finished, the strength of the stage will grow to the final value, when the gate is charged to the voltage reference level or a predefined product of the time constant and that voltage. Then, when the terminal is switched from low to high by the attached switching logic 23, 24, such as the differential pull-down circuitry, then, for a time constant formed by LC structure, the load is pulled up with high strength until the gates of transistors 21, 22 are discharged to a lower level.

Respectively, the use of such buffers in voltage controlled oscillators provides changing the frequency of the oscillator by changing the voltage.

In FIG. 13, a similar buffer stage is shown, where transistors 31, 32 and 36, 37 operate in the same way as transistors 21, 22 and 26, 27 in FIG. 12, but with the use of additional transistors 381, 382, 383, 384 acting as a low pass filter for load control voltage VT and VT1. Additional voltages VR, VR1 control the strength of transistors 381, 382 and 383, 384, respectively. These voltages VR, VR1 serve to create a certain shift with respect to voltages VT, VT1. This shift is obtained by using a transistor, such as transistors 381, 382 and 383, 384, as a diode transistor and supplying this transistor with a small current.

The embodiment shown in FIG. 13 is especially advantageous to provide circuits of reduced size, or, when resistors cannot be used due to their capacitance.

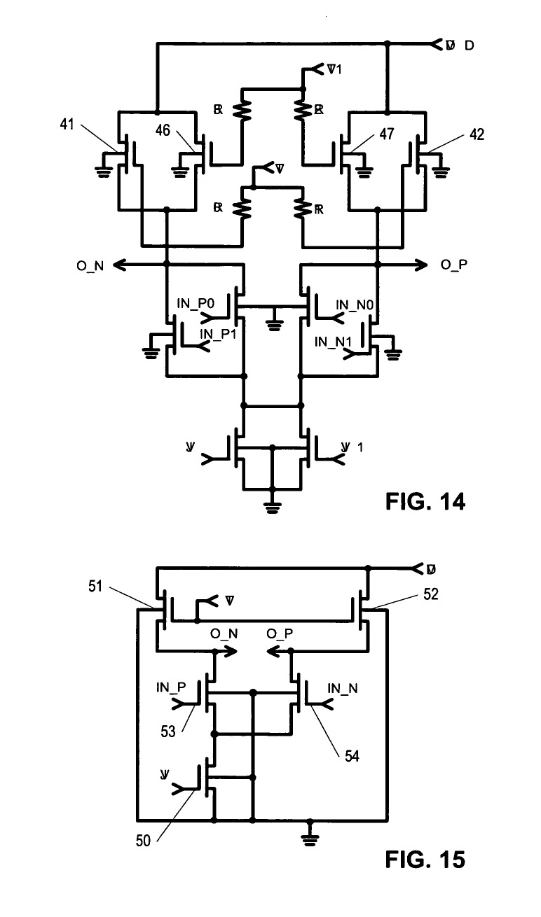

In FIG. 14, another example embodiment of the buffer stage for use in the present invention is shown, wherein resistors R0, R1, R2, R3 with their parasitic capacitance are used as a low pass filter for load control voltage VT and VT1. Resistors R0, R1 are connected in series with the gates of transistors 41, 42, while resistors R3, R2 are connected in series with the gates of transistors 46, 47.

In operation, resistors RO, R1, R2, R3 dynamically modulate the strength of the respective transistors during switching. The transistor itself has a gate capacitance. In combination with resistor, these form an equivalent RC network, which gives a delay when this time constant is close to the switching time that changes the current in the pull-up dynamically. This is described in detail in WO 03/100974 by the same inventors and US application “Pull-up for high speed structures” filed on the same date with the present application.

The additional advantage of the above described circuits is that by switching inputs/outputs, it can be easily converted from buffer stages into inverters, when required.

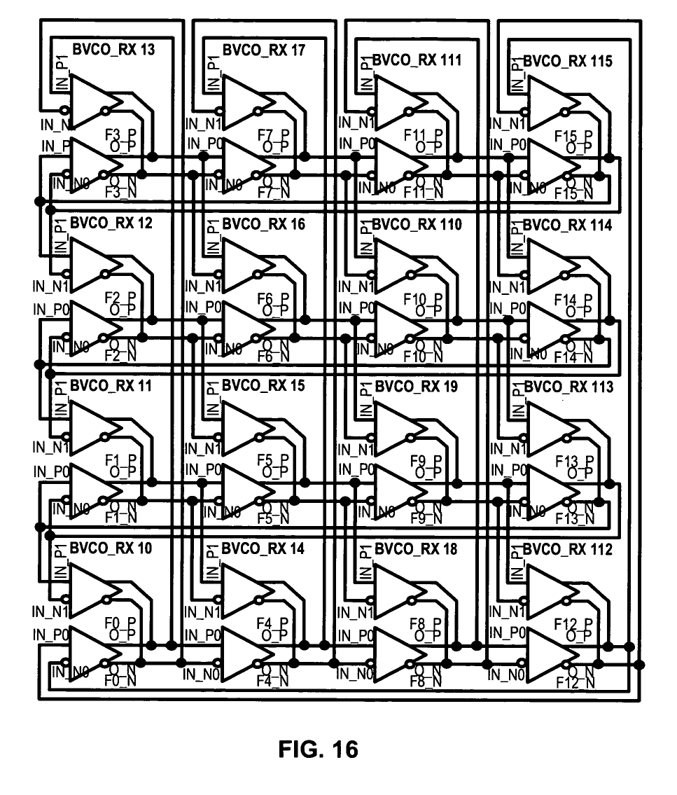

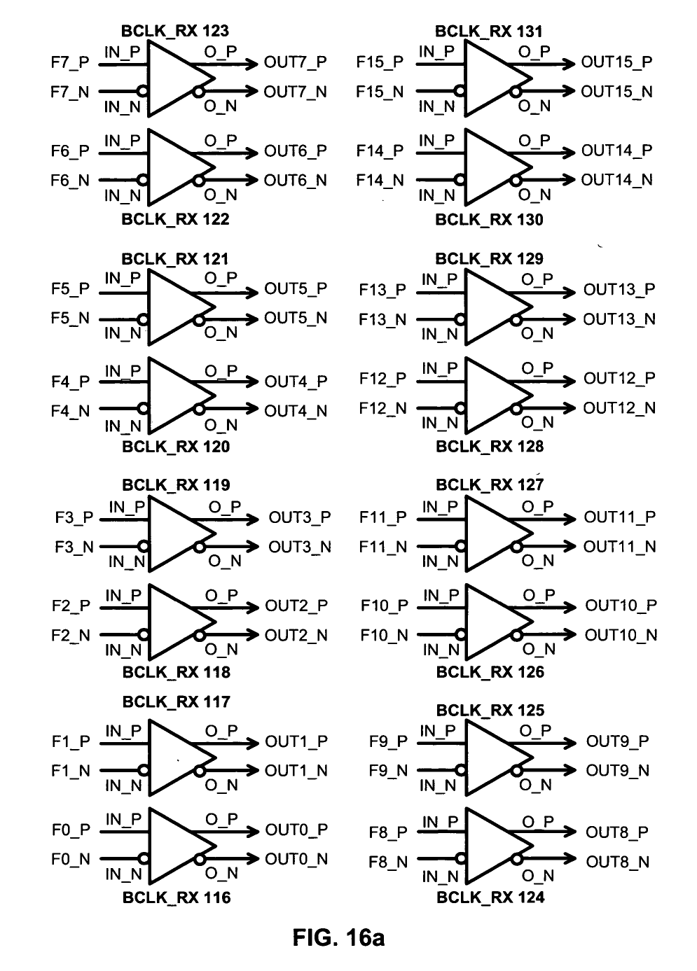

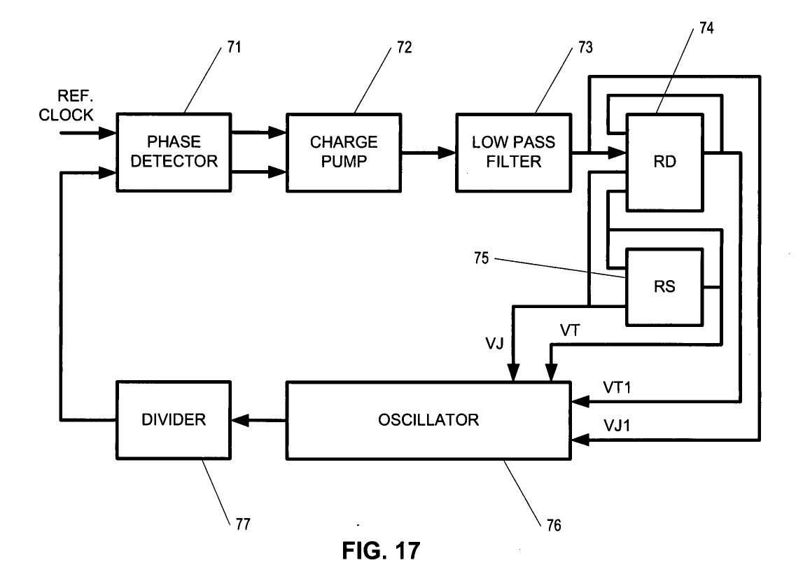

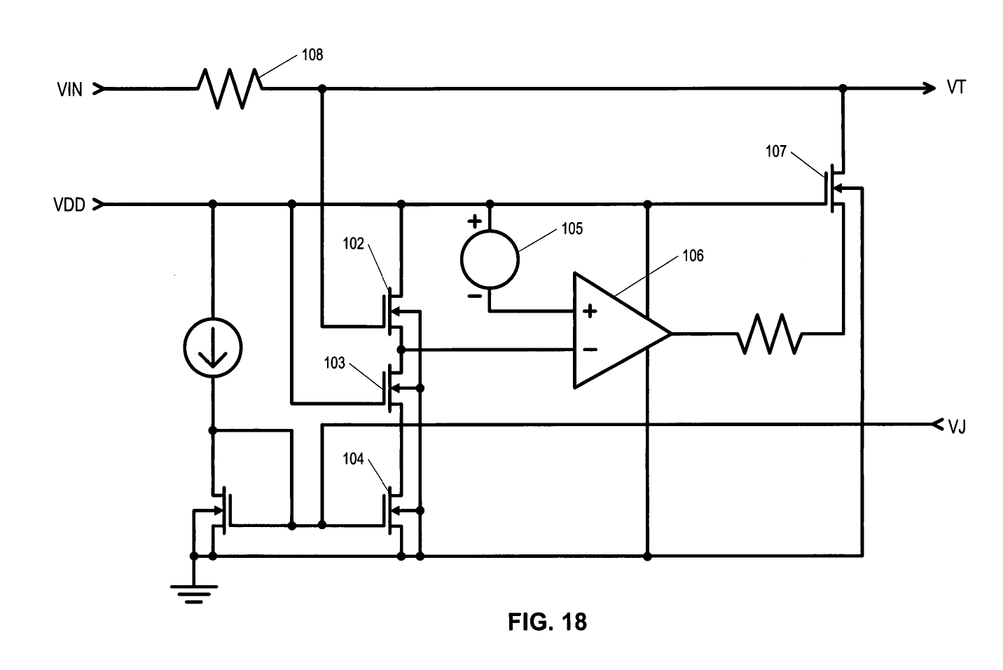

FIG. 15 depicts a schematic representation of another implementation of differential buffer stage called “isolation buffer”. It is particularly suitable for use in a supplemental circuit shown in FIG. 16a for a ring oscillator shown in FIG. 16. It will preferably be implemented by using a circuit architecture roughly corresponding to approximately one-half of the buffer stage depicted in FIG. 12 (see also description of FIG. 17 in U.S. Pat. No. 5,717,362).

The buffer of FIG. 15 is configured to receive a differential signal through an input differential stage having input transistors 53, 54. Complementary outputs are provided by the buffer at output ports O_N and O_P. The buffer stage further includes an NMOS transistor current source 55 to which is applied the current source bias VJ. The externally-supplied oscillation control voltage VT is applied to NMOS transistors 51 and 52.

It shall be also mentioned that while the circuit of FIG. 15 can be used to built up a ring oscillator according to the invention, it can be further doubled to create a simplest example implementation of a differential buffer circuit suitable to built up array oscillators according to the invention.

It shall be appreciated that the circuits shown here operate only with N type enhancement mode MOSFETs, as the P Type Devices which are used in the prior art for pull-ups operate with the opposite effect.

To provide the operation of buffer stages as shown in FIG. 15, with N-type MOSFET transistors, a conventional replica bias circuitry can be used, e.g. as described in FIG. 18 of U.S. Pat. No. 5,717,362.

However, the problems with conventional replica circuitry is that the load voltage VT of a replica bias circuit shall exceed the supply voltage VDD for at least a threshold voltage of a transistor to which this voltage is applied. Otherwise, the pull up strength of the transistor significantly degrades at small voltage drops. Thus, generally, VT>>VDD, and in some cases, VT can be as high as 2VDD−VRef. On the other hand, overvoltages on transistors deteriorate the transistor's parameters and cause their fast degradation.

To fulfil both requirements, i.e. to provide a controlled supply voltage in the absence of transistor overvoltages, a specially designed replica bias circuitry most suitable for the operation of the above buffer with NMOS transistors is provided according to the present invention.

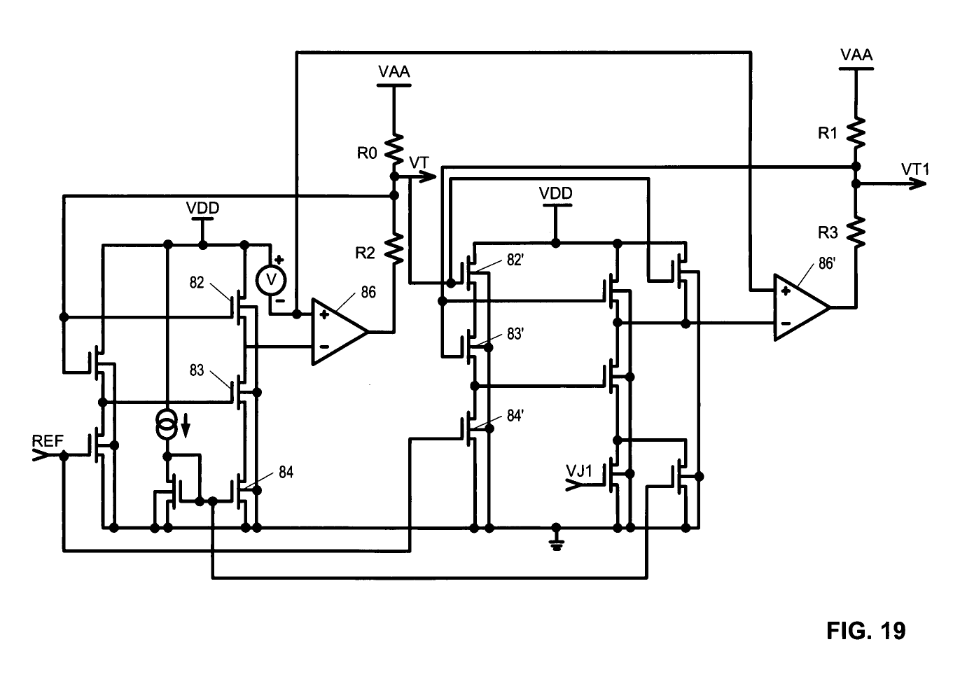

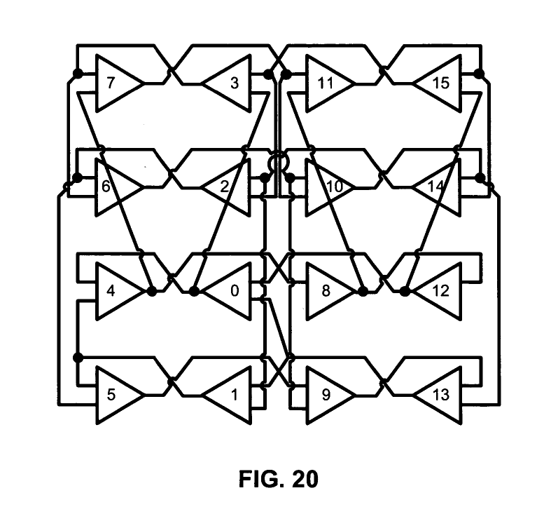

Example embodiments of a replica bias circuitry according to the present invention are shown in FIGS. 18 and 19.

A replica bias circuitry shown in FIG. 18 represents in a most general form a circuitry for generating a load voltage VT based on supply voltage VDD and control voltage VJ. VJ is externally supplied static bias providing oscillation control.

The circuitry comprises a cascade of transistors 102, 103, 104, where transistor 102 is a load transistor, transistor 103 is optional and serves for determining the operation point of the load transistor, and transistor 104 operates as a current source. The operation point of a load element can be defined by a combination of two parameters ΔU/Iop, where lop is an operating current and ΔU is the full voltage drop on the element and characterises the strength of a load element, i.e. its differential impedance.

The replica bias circuitry of FIG. 18 further comprises an operational amplifier 106 having one input connected to the reference voltage from a source 105 of a reference voltage, and another input connected to the source of transistor 102. The output of the amplifier is connected to the source of transistor 107, having its gate connected to the supply voltage VDD. A resistor 108 is connected in series between an input voltage VIN and the gates of the load transistor 102.

The replica bias circuitry operates as follows.

A control voltage VJ is supplied to transistor 104 to provide a current flowing in transistors 102, 103, 104. The difference between a voltage drop in transistor 102 and the reference voltage is amplified by operational amplifier 106. The output of the amplifier 106 through a negative feedback can be used to control the load voltage VT using a transistor 107 and resistor 108 and coupling the load voltage VT to the gate of transistor 102. As a result, the current generated in transistor 107 depends on the voltage at the output of the amplifier 106 and, using resistor 108, we can adjust the load voltage VT accordingly. In a balanced state, the voltage drop on transistor 102 approximates the reference voltage.

Another example implementation of a replica bias circuitry with two replicas, static VT and dynamic VT1, is shown in FIG. 19.

The circuitry comprises two operational amplifiers (OpAmps) 86 and 86′, each having a feedback loop formed of transistors 82, 83, 84 and 82′, 83′, 84′, respectively.

VJ is externally supplied static bias. VJ1 and VT1 derived from it provide oscillation control. VJ1 is a control voltage which provides a compliance of the VCO frequency to a required value. VT1 provides a required amplitude of the differential signal in VCO. Reference current VR is supplied to OpAmps 86 and 86′, so as to form VT1 via feedback loops using VT and VJ.

The replica bias circuitry of FIG. 19 is specifically adapted to provide the required voltage levels VT and VT1 to control differential buffer stages made of MOS transistors, in particular, to generate VT which exceeds a supply voltage VDD.

In conventional circuitries, to provide operation of pull ups, such as pull up 82, it is required that VAA >>VDD. This typically causes overvoltages of transistors. The above problem is solved by the replica bias circuitry shown in FIGS. 18a and 18b, which provide normal operation of a cascade of transistors, while no one voltage exceeds the admissible level. The VAA requires small currents while the voltage can be twice as high as VDD.

In the example implementation of the replica bias circuitry of FIG. 19, VT is used to form an initial voltage level to start up a voltage generator, while VT1 is used for a more accurate adjustment of the thus obtained voltage level.

The generated VT can be also used to provide a required amplitude of a differential signal in VCO. Reference current VIN is supplied to OpAmps 86, 86′, so as to form VT1 via feedback loops using VT and VJ.

Referring back to FIG. 11, the key point of the present invention is that all the stages can be the same, or can be any combination of inverters and buffers, subject to each ring having a 180 degrees phase shift or even multiple thereof (3*180, 5*180 etc), and all the feedback paths are the same, except that at least one path shall have the opposite polarity to all of or the majority of the others. This last point is crucial to the circuits operating in fundamental mode. All the feedback paths are shown in FIG. 11. Note that all the feedback paths are the same, except for one stage.

The operation of this embodiment is best understood by labeling the phases on each of the interconnections. For this purpose, the S input to the first inverter P0, will be regarded as 0 phase.

Each ring oscillator comprises 4 stages. Therefore, the phase difference between the input and output of each stage is 45 degrees (180 degrees divided by 4). The C input can be assumed to be the same as the S input: that is, each stage acts like two differential inverters/buffers in parallel. This means the phase of the output of each stage will be the mean of the two inputs plus 45 degrees. There are many possible implementations of such a twin input stage.

FIG. 16 is a schematic representation of a ring oscillator VCO, which depicts the exemplary array oscillator according to the invention. The array oscillator generates 4*4 phases from 4 interconnected ring oscillators of 4 stage each. Each stage is a differential buffer stage, such as described with reference to FIGS. 12, 13 or 14. The output frequency of each ring of the array is nominally ½D, where D is the delay through one ring.

To design the required array oscillator, a ring oscillator to achieve the required frequency is first designed. The preferred manner for this design is the use of one inverter stage followed by sufficient buffers to create the delay required. The number of phases generated by the array is m rows×n stages per row, so once the ring is defined, the number of rings can be determined by dividing the number of phases required by the number of stages in each ring. In case a fractional number of rings is obtained, it shall be made round.

The feedback should preferably be from N+1 or N−1, as this minimises power consumption, but any other phase can be selected, such that the input to each stage has the same phase relationship. The phases of the two S and C inputs to each stage must overlap at least partially: that is they must be less than 180 degrees of each other (or 180/n where n is an even number).

To achieve this requirement of the same phase relationship for each stage, it is necessary to invert one of the feedback signals: for example if 180+9 degrees is generated, to obtain 9 degrees it is necessary to invert the signal such as by swapping the two lines of a differential input.

Thus, a voltage controlled oscillator according to the invention comprises an array oscillator controlled by the use of a bias arrangement where changes in the bias cause changes in the delay through each stage.

The array is preferably controlled by the use of two arrangements: VT,VT1—load control voltage and VJ, VJ1—bias control voltage. VT(VT1) depends on VJ(VJ1) and is derived (formed) from these voltages by the use of a replica bias circuitry as shown further in FIG. 19.

VJ is an externally supplied static (i.e., constant) current source bias which serves (together with VT): (i) to avoiding suppression of oscillation during the startup; and (ii) to narrowing oscillation control range and, thereby, providing smoother and faster regulation of oscillation.

VJ1 is a dynamic current source bias; in other words, the changes in the bias (also in VT1) cause changes in the delay through each stage of the array oscillator.

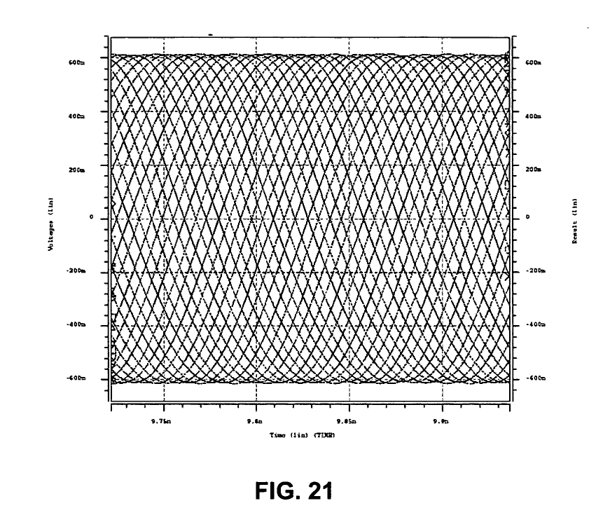

The rings of the oscillators of the type shown in FIG. 11 and those described by the present invention (see the interconnections of this array oscillator in FIG. 19), oscillate in a stable manner and generally do not require any initialisation, as they revert to fundamental mode automatically. Simulation results of the array oscillator shown in FIG. 11 are presented in FIG. 21.

If initialisation is required, the rings can be made open by substituting a logic function such as an NOR gate for one or more stages in each ring and applying a reset signal to the extra input of the NOR. Other gates such as NAND, XOR can perform a similar function.

It is possible to use the present invention as a VCO by the use of variable bias stages, by the use of varicap diodes, or other delay modification mechanism. The use of variable bias stages is preferred because a common biasing scheme will cause all stages to vary by the same amount.

A further improvement of the array oscillation shown in FIG. 16 can be obtained by using a supplemental circuit shown in FIG. 16a, which uses buffer stages shown in FIG. 15, which prevents from affecting the array oscillator by the noise generated by external load devices connected to the array oscillator.

FIG. 17 shows a PLL with very low phase noise with VCO as described with reference to FIG. 16 above. RS and RD represents static and dynamic replica bias circuitry, respectively. The phase lock loop comprises a phase detector 71, a charge pump 72, low pass filter 73, a static and dynamic replica bias circuitries RS, RD, voltage controlled oscillator 76 and frequency divider 77.

The VCO shown in FIG. 16 can be used in a phase locked loop (PLL) as shown in FIG. 17, whereby the frequency of the VCO 76 is set by the variable divider 77. The output of the divider 77 is compared with a reference clock such as from a crystal oscillator, and this phase comparator 71 drives a charge pump 72, which in turn drives the bias control of the VCO 76. The array oscillator VCO 76 will then generate multiple phases at a frequency set by the reference clock times the reciprocal of the divider 77. PLL theory for implementing and analysing such structures is well known. FIGS. 12 to 15 show differential buffer circuitry for some main elements of PLL.

One skilled in the art will appreciate that the present invention may be practiced by other than the described embodiments, which are presented for purposes of illustration and not of limitation, and that the present invention is limited only by the appended claims.

We claim:

1. A differential buffer stage configured to receive differential signals at input signal ports (IN_P, IN_N) and to provide complementary buffer stage outputs at output ports (O_P, O_N), comprising:
a first (51) and second (52) load elements, connected with their gates to a load control voltage (VT), for controlling the amplitude of output signals (O_P, O_N), each load element including at least one N-type MOSFET transistor (51, 52) for converting current into voltage;
at least one static current source (50) to which is applied a static current source bias (VJ),
at least one pair of switch transistors (53, 54);
wherein the buffer stage is controlled by at least one set of two voltages, including static load control voltage, VT, and static bias control voltage, VJ, where VT depends on VJ and is derived from this voltage by the use of a replica bias circuitry.

2. A differential buffer stage as claimed in claim 1 wherein each load element comprises one N-type MOSFET transistor (21; 22) connected with its gate to a static load control voltage, VT, the stage having one static current source (50) to which is applied a static current source bias (VJ).

3. A differential buffer stage as claimed in claim 1, further comprising a low pass filter for the load control voltage (VT, VT1).

4. A differential buffer stage as claimed in claim 3, wherein the low pass filter is formed by at least one transistor (381, 382, 383, 384).

5. A differential buffer stage according to claim 4, wherein the said transistor is supplied with a voltage from a voltage reference.

6. A differential buffer stage as claimed in claim 3, wherein the low pass filter is formed by at least one resistor (R0, R1, R2, R3).

7. A differential buffer stage as claimed in claim 1, wherein the load element comprises a N type MOSFET transistor with a resistor in parallel, wherein the transistor is supplied with a voltage from a voltage reference.

8. A differential buffer stage as claimed in claim 7, wherein the resistor of the load element comprises two elements connected in parallel with the N type MOSFET with a tap to the terminal of the load element between the two resistor elements.

9. A differential buffer stage according to claim 7, wherein an additional resistor is placed between the source of the N Type MOSFET and the terminal of the load element.

10. A differential buffer stage according to claim 7, wherein the load element further comprises a resistor in series with the gate.

11. A differential buffer stage according to claim 7, wherein the resistor is selected such that the resistor in conjunction with the N-Type MOSFET gate capacitance has a time constant which minimises the switching time of the logic elements which the pull up serves.

12. A differential buffer stage according to claim 7, further comprising a resistor connected between the terminal of the load element and the load control voltage.

13. A differential buffer stage according to claim 7, further comprising a resistor connected between the source of N type MOSFET and the terminal of the load element.

14. A differential buffer stage according to claim 7, wherein the load element comprises a N type MOSFET with a resistor placed across the source and drain of the MOSFET and another resistor placed between the source of the N Type MOSFET and the terminal of the load element.

15. A differential buffer stage according to claim 1 wherein the load element comprises a N type MOSFET with a resistor connected across the source and drain of the MOSFET and another resistor connected between the terminal of the load element and a voltage supply higher than the voltage to which the drain of the MOSFET is connected, with the current split between the two power supplies.

16. A differential buffer stage as claimed in claim 1 further comprising a second pair of switch transistors (25, 28).

17. A differential buffer stage as claimed in claim 1 wherein each load element comprises a second N-type MOSFET transistor (26; 27) for dynamic modulation of the load, so that one transistor (21, 22) in each load element is connected with its gate to a static load control voltage (VT) and the other transistor (26, 27) in each load element is connected with its gate to a dynamic load control voltage (VT1), the stage further comprising a second current source to which is applied a dynamic current source bias (VJ1).

18. A differential buffer stage configured to receive differential signals at input signal ports (IN_P1, IN_N1) and input coupling ports (IN_P0, IN_N0) and to provide complementary buffer stage outputs at output ports (O_P, O_N) comprising:
first (21, 22) and second (26, 27) load elements, connected respectively to first, static, and second, dynamic, load voltages (VT, VT1) for controlling the amplitude of output signals (O_P, O_N), each load element including a set of N-type MOSFET transistors (21, 22 and 26, 27), for converting current into voltage;
wherein transistors (26,27) are connected in parallel with the drains of transistors (21,22), for dynamic modulation of the load of the differential stage;
a static current source (20) and a dynamic current source (29) to which are applied, respectively, a static and dynamic current source biases (VJ and VJ1),
two pairs of switch transistors (23, 25, 24, 28); the drains of the load transistors (21, 22 and 26, 27) being connected through switch transistors (23, 24, 25, 26) to the current source transistors (20, 29) controlled by current source biases VJ and VJ1;
wherein the buffer stage is controlled by two sets of voltages, including load control voltages VT,VT1 and bias control voltages VJ, VJ1, where VT(VT1) depends on VJ(VJ1) and is derived from these voltages by the use of a replica bias circuitry.

19. A differential buffer stage as claimed in claim 1, wherein the replica bias circuitry comprises:
a cascade of at least one load transistor (102) and at least one transistor (104) acting as a current source,
a source (105) of a reference voltage,
an operational amplifier (106) having one input connected to the reference voltage and another input connected to the source of the load transistor (102);
a transistor (107) having its gate connected to a supply voltage (VDD) and source connected to the output of the amplifier (106), for avoiding overvoltages of the said cascade of transistors; and
a resistor (108) connected in series between an input voltage VIN and the gates of the load transistor (102);
wherein
a bias control voltage (VJ) is supplied to the transistor current source (104) to provide a current flowing in the said cascade of transistors (102, 104),
a load control voltage (VT) is supplied to the gates of the said load transistor (102) and is further coupled to resistor 108;
thereby the difference between a voltage drop in the load transistor (102) and the reference voltage is amplified by the operational amplifier (106) to control a load voltage (VT) through a feedback formed of said transistor (107) and resistor (108).

20. A differential buffer stage as claimed in claim 16, wherein the replica bias circuitry includes at least two replicas for providing, respectively, amplitude control voltages VT, VT1 for controlling an amplitude of the output signal and frequency control voltages VJ, VJ1 for controlling the frequency of the output signal, each said replica circuit comprising:
a cascade of at least one load transistor (82, 82′) and at least one transistor (84, 84′) acting as a current source,
an operational amplifier (86, 86′) having one input connected to a reference voltage and another input connected to the source of the load transistor (82, 82′);
a first resistor (R2; R3) connected between the output of the amplifier and a load voltage (VT, VT1), for avoiding overvoltages of the said cascade of transistors (82, 84, 82′, 84′),
a second resistor (R0, R1) connected between the supply voltage (VAA) and the gate of the load transistor (82, 82′);
wherein
a bias control voltage (VJ, VJ1) is supplied to the transistor current source (84, 84′) to provide a current flowing in the said cascade of transistors (82, 84, or 82′, 84′),
a load voltage (VT, VT1) is coupled to the gates of the said load transistor (82, 82′) and is further coupled to resistors R0, R1;
thereby the difference between a voltage drop in the load transistor (82, 82′) and the reference voltage is amplified by the operational amplifier (86, 86′) to control a load voltage (VT, VT1) through a feedback formed by said cascade of transistors (82,84, 82′,84′) and resistors R2, R3.

21. A differential buffer stage as claimed in claim 19, wherein each replica bias circuitry further comprises a transistor (103) for determining the operation point of a load transistor (102).

22. A differential buffer stage as claimed in claim 19, wherein each replica bias circuitry comprises a duplicate cascade of transistors.

23. A replica bias circuitry for providing control voltages for controlling a high speed differential buffer stage formed of NMOS elements, the circuitry comprising:
a cascade of at least one load transistor (102) and at least one transistor (104) acting as a current source,
a source (105) of a reference voltage,
an operational amplifier (106) having one input connected to the reference voltage and another input connected to the source of transistor (102);
a transistor (107) having its gate connected to a supply voltage (VDD) and source connected to the output of the amplifier (106); and
a resistor (108) connected in series between an input voltage VIN and the gates of the load transistor (102);
wherein
a control voltage (VJ) is supplied to the transistor current source (104) to provide a current flowing in the said cascade of transistors (102, 104),
a load voltage (VT) is supplied to the gates of the said load transistor (102) and is further coupled to resistor 108; and
the difference between a voltage drop in the load transistor (102) and the reference voltage being amplified by the operational amplifier (106) to control a load voltage (VT) through a feedback formed of said transistor (107) and resistor (108).

24. A replica bias circuitry as claimed in claim 23, further comprising a transistor (103) for determining the operation point of the load transistor (102).

25. A replica bias circuitry as claimed in claim 23, further comprising a second resistor connected in series with the output of the amplifier.

26. A replica bias circuitry as claimed in claim 23, wherein the differential buffer stage is as claimed in claim 1.

27. A replica bias circuitry as claimed in claims 23, further comprising a second replica.

28. A replica bias circuitry as claimed in claim 27, wherein the second replica bias circuit provides for an amplitude control voltage VT1 for controlling an amplitude of the output signal, and frequency control voltage VJ1 for controlling the frequency of the output signal.

29. A replica bias circuitry as claimed in claim 23, wherein each replica bias circuitry comprises a duplicate cascade of transistors.

30. A replica bias circuitry as claimed in claim 27, wherein the differential buffer stage is as claimed in claim 16.

31. A ring oscillator circuit comprising a plurality of at least two interconnected buffer stages including at least one, or any integer odd number of inverting stages and a series of non-inverting stages, such that there is a 180 degrees phase shift or odd multiple thereof through the ring oscillator; wherein each buffer stage is as claimed in claim 1.

32. A ring oscillator circuit comprising a plurality of at least two interconnected buffer stages including at least one, or any integer odd number of inverting stages and a series of non-inverting stages, such that there is a 180 degrees phase shift or odd multiple thereof through the ring oscillator; wherein each buffer stage is as claimed in claim 18.

33. A ring oscillator circuit comprising a plurality of at least two interconnected buffer stages including at least one, or any integer odd number of inverting stages and a series of non-inverting stages, such that there is a 180 degrees phase shift or odd multiple thereof through the ring oscillator,
wherein each buffer stage comprises a set of load elements so that at least one load element is formed of N-type MOSFET transistors; the load elements being connected to control voltages for controlling the amplitude of output signals, and connected through switch transistors to current source transistors controlled by current source biases for controlling the frequency of output signals.

34. A ring oscillator circuit as claimed in claim 33, wherein the control voltages are generated by a replica bias circuitry as claimed in claim 23.

35. An array oscillator circuit comprising:
a plurality of at least two ring oscillators, each ring oscillator having a plurality of at least two interconnected buffer stages including at least one, or any integer odd number of inverting stages and a series of non-inverting stages, such that there is a 180 degrees phase shift or odd multiple thereof through the ring oscillator; wherein each buffer stage is as claimed in claim 16.

36. An array oscillator circuit comprising:
a plurality of at least two ring oscillator, each ring oscillator having a plurality of at least two interconnected buffer stages including at least one, or any integer odd number of inverting stages and a series of non-inverting stages, such that there is a 180 degrees phase shift or odd multiple thereof through the ring oscillator; wherein each buffer stage is as claimed in claim 18.

37. An array oscillator circuit comprising:
a plurality of at least two ring oscillators, each ring oscillator having a plurality of at least two interconnected buffer stages including at least one, or any integer odd number of inverting stages and a series of non-inverting stages, such that there is a 180 degrees phase shift or odd multiple thereof through the ring oscillator,
wherein each buffer stage comprises a set of load elements so that at least one load element is formed of N-type MOSFET transistors; the load elements being connected to control voltages for controlling the amplitude of output signals, and connected through switch transistors to current source transistors controlled by current source biases for controlling the frequency of output signals.

38. An array oscillator circuit according to claim 37, wherein the two sets of voltages, including load control voltages and bias control voltages, are generated by the use of a replica bias circuitry, so that the load control voltages depend on bias voltages and are derived from these voltages.

39. An array oscillator circuit according to claim 37, wherein each set of voltages includes a static and dynamic voltage.

40. An array oscillator circuit according to claim 37, wherein the replica bias circuitry is as claimed in claim 27.

41. An array oscillator circuit according to claim 35, wherein the stages are coupled to other ring oscillators in the array such that the phase shift through each stage is the same throughout the array, with all the feedback paths being of the same type except for one path which shall be of the opposite polarity to the others.

42. An array oscillator of claim 35, comprising at least two, or any even number of ring oscillators, each ring oscillator has at least 2 stages, including one inverting and one non-inverting stage.

43. An array oscillator of claim 42, comprising four ring oscillators, each having one inverting stage and three non-inverting stages.

44. An array oscillator of claim 34, wherein all stages are formed from identical differential inverters.

45. An array oscillator of claim 34, wherein non-inverting stage are formed by swapping two inverting inputs to the stage.

46. An array oscillator of claims 34, wherein the gain from one input to output is more than 1.

47. An array oscillator as claimed in claim 35 wherein input coupling ports of the differential buffer circuit are assumed to be the same as input signal ports.

48. An array oscillator as claimed in claim 35 wherein each buffer stage acts like two differential inverters/buffers in parallel.

49. An array oscillator as claimed in claim 35, further comprising a supplemental circuit configured of isolation buffer stages, which prevents from affecting the array oscillator by the noise generated by external load devices connected to the array oscillator.

50. A voltage controlled oscillator comprising an array oscillator of claim 34, where the array is controlled by the use of a replica bias circuitry where changes in the bias cause changes in the delay through each stage.

51. A voltage controlled oscillator as claimed in claim 50, wherein the array is controlled by the use of two arrangements, including load control voltages VT,VT1 and bias control voltages VJ, VJ1, wherein VT(VT1) depends on VJ(VJ1) and is derived from it by the use of a replica bias circuitry as claimed in claims 16 to 19 and VJ is a externally supplied static (constant) current source bias and VJ1 is a dynamic current source bias.

52. A phase locked loop with very low phase noise comprising a phase detector, a charge pump, low pass filter, a static and dynamic replica bias circuitries, voltage controlled oscillator and frequency divider, wherein the voltage controlled oscillator is as claimed in claim 50.
